(19) United States
(12) Patent Application Publication
(10) Pub. No.: US 2013/0240971 A1
(43) Pub. Date: Sep. 19, 2013

(54) NONVOLATILE SEMICONDUCTOR STORAGE DEVICE AND METHOD OF MANUFACTURING THE SAME

(71) Applicants: Hideto TAKEKIDA, Nagoya (JP); Fumie Kikushima, Yokkaichi (JP)

(72) Inventors: Hideto TAKEKIDA, Nagoya (JP); Fumie Kikushima, Yokkaichi (JP)

(73) Assignee: KABUSHIKI KAISHA TOSHIBA, Tokyo (JP)

(21) Appl. No.: 13/616,990

(22) Filed: Sep. 14, 2012

(30) Foreign Application Priority Data
Mar. 15, 2012 (JP) 2012-058755

(51) Int. Cl. H01L 49/02; H01L 27/07

(52) U.S. Cl. CPC H01L 28/20; H01L 27/0738
USPC 257/316; 257/315; 438/382

(57) ABSTRACT

A nonvolatile semiconductor storage device including a semiconductor substrate; a first semiconductor region being formed in the semiconductor substrate and being delineated by a first element isolation trench filled with an isolation insulating film; a second semiconductor region being formed in the semiconductor substrate and being delineated by a second element isolation trench filled with the isolation insulating film; a memory cell transistor formed in the first semiconductor region, the memory cell transistor including a first gate insulating film, a memory gate electrode including a stack of, a first conductive film, a second gate insulating film, and a second conductive film formed above the first gate insulating film; a resistor formed in the second semiconductor region, the resistor including a stack of the first gate insulating film and the first conductive film; and a first and second contact plug contacting the first conductive film of the resistor.

### CROSS-REFERENCE TO RELATED APPLICATION(S)

This application is based upon and claims the benefit of priority from Japanese Patent Application No. 2012-058755, filed on, Mar. 15, 2012 the entire contents of which are incorporated herein by reference.

### FIELD

Embodiments disclosed herein generally relate to a nonvolatile semiconductor storage device and a method of manufacturing the same.

### BACKGROUND

A NAND flash memory, which is one example of a nonvolatile semiconductor storage device, is typically configured with memory cell transistors having a stacked gate structure in which a stack of floating gate electrode, an insulating film, and a control gate electrode are provided above a semiconductor substrate. In such stacked gate structure, the floating gate electrode serves as a charge storage layer. Multiplicity of memory cell transistors is arranged in rows and columns to form a memory cell array. The memory cell transistors within the memory cell array are grouped into units of NAND strings also referred to as NAND cell units. Each NAND cell unit includes multiple memory cell transistors which are series connected in the column direction of the memory cell array such that each memory cell transistor shares the source/drain region with the adjacent memory cell transistor. Further, a select transistor is provided on each end of the string of series connected memory cell transistors. Thus, the memory cell array is a collection the NAND cell units arranged in rows and columns. The NAND cell units aligned in the row direction are grouped into NAND cell blocks. The select transistors aligned in the row direction are interconnected by a common select gate line, whereas the memory cell transistors aligned in the row direction are interconnected by a control gate line also known as a word line.

The above described memory cell array is driven by peripheral circuitry configured by logical circuits such as timers and switches and by step-up circuits. A resistor is a typical component of such circuits and the resistor utilizes the diffusion layer of the semiconductor substrate for producing the resistance. Thus, when the resistor needs to be formed in smaller areas, typically due to densification, impurities are introduced in relatively lighter concentration in order to increase the resistivity.

Problems encountered under such approach include failure in obtaining the targeted resistivity and unintended variation in resistivity between the resistors. These problems are caused by disturbs typically originating from thermal treatment performed after ion implantation of impurities or from contamination which occurs when the surface of the substrate is exposed during the manufacturing process flow. Especially because impurities are often introduced prior to the formation of the element region within the semiconductor substrate or formation of the gate structure, the impact of the disturbs become greater.

In a NAND flash memory taking a stacked gate structure as described earlier, the floating gate electrode is typically configured by polycrystalline silicon which exhibits relatively high resistivity. Thus, the floating gate may be utilized as a resistor as an alternative to the first approach. More specifically, a contact may be formed that is connected with the control gate electrode and further connected with the underlying floating gate electrode by way of an opening defined through the insulating film located between the control gate electrode and the floating gate electrode.

This alternative approach is also affected by problems such as unintended variation in resistivity which typically originates from additional resistance components including contact resistance produced at the interface between the contact and the control gate electrode and the contact resistance between the control gate electrode and the floating gate electrode. These additional resistance components are presumed to cause the unintended variance in resistivity as well as the nonlinearity of the resistor and thus, have affected the stability of the resistors.

### BRIEF DESCRIPTION OF THE DRAWINGS

FIG. 1 is a schematic block diagram partially indicating the electrical configuration of a memory cell region and a peripheral circuit region of a NAND flash memory device.

FIG. 2A is a schematic plan view partially illustrating the memory cell region.

FIG. 2B is a schematic plan view of a peripheral circuit transistor.

FIG. 2C is a schematic plan view of a resistor prior to the formation of an interconnect pattern.

FIG. 2D is a schematic plan view of the resistor after the formation of the interconnect pattern.

FIG. 3A is schematic vertical cross sectional view taken along line 3A-3A of FIG. 2C.

FIG. 3B is schematic vertical cross sectional view taken along line 3B-3B of FIG. 2B.

FIG. 3C is schematic vertical cross sectional view taken along line 3C-3C of FIG. 2A.

FIG. 3D is schematic vertical cross sectional view taken along line 3D-3D of FIG. 2A.

FIGS. 4A to 12A are schematic vertical cross sectional views taken along line 3A-3A of FIG. 2C and each depicts one phase of the manufacturing process flow.

FIGS. 4B to 12B are schematic vertical cross sectional views taken along line 3B-3B of FIG. 2B and each depicts one phase of the manufacturing process flow.

FIGS. 4C to 12C are schematic vertical cross sectional views taken along line 3C-3C of FIG. 2A and each depicts one phase of the manufacturing process flow.

FIGS. 4D to 12D are schematic vertical cross sectional views taken along line 3D-3D of FIG. 2A and each depicts one phase of the manufacturing process flow.

FIGS. 13A and 14A are schematic vertical cross sectional views taken along line 3A-3A of FIG. 2C and each depicts one phase of the manufacturing process flow of a second embodiment.

FIGS. 13B and 14B are schematic vertical cross sectional views taken along line 3B-3B of FIG. 2B and each depicts one phase of the manufacturing process flow of a second embodiment.

FIGS. 13C and 14C are schematic vertical cross sectional views taken along line 3C-3C of FIG. 2A and each depicts one phase of the manufacturing process flow of a second embodiment.

FIGS. 13D and 14D are schematic vertical cross sectional views taken along line 3D-3D of FIG. 2A and each depicts one phase of the manufacturing process flow of a second embodiment.

### DESCRIPTION

In one embodiment a nonvolatile semiconductor storage device includes a semiconductor substrate; a first semiconductor region being formed in the semiconductor substrate and being delineated by a first element isolation trench filled with an isolation insulating film; a second semiconductor region being formed in the semiconductor substrate and being delineated by a second element isolation trench filled with the isolation insulating film; a memory cell transistor formed in the first semiconductor region, the memory cell transistor including a first gate insulating film, a memory gate electrode including a stack of, a first conductive film, a second gate insulating film, and a second conductive film formed above the first gate insulating film; a resistor formed in the second semiconductor region, the resistor including a stack of the first gate insulating film and the first conductive film; and a first and second contact plug contacting the first conductive film of the resistor.

In one embodiment a method of manufacturing a nonvolatile semiconductor storage device includes forming a first gate insulating film above a semiconductor substrate, a first conductive film above the first gate insulating film, and a first insulating film above the first gate insulating film; forming an element isolation trench into the semiconductor substrate by etching the first conductive film, the first gate insulating film, and the semiconductor substrate using the first insulating film as a mask; filling the element isolation trench with an element isolation insulating film; removing the first insulating film located in a memory cell transistor forming region while leaving the first insulating film located in a resistor forming region; forming a second gate insulating film in the resistor forming region and the memory cell transistor forming region; forming a second conductive film above the second gate insulating film; partially etching the second conductive film, the second gate insulating film, and the first conductive film in the memory cell transistor forming region to form a memory gate electrode; partially etching the second conductive film in the resistor forming region; etching the second gate insulating film in the resistor forming region to form a contact region; forming a second insulating film so as to cover the memory gate electrode and the remaining second conductive film in the resistor forming region; forming a third insulating film above the second insulating film; and forming a first contact plug and a second contact plug extending through the third insulating film, the second insulating film, and the first insulating film in the resistor forming region.

Embodiments are described hereinafter with references to the accompanying drawings to provide illustrations of the features of the embodiments. Elements that are identical or similar are represented by identical or similar reference symbols across the figures and are not redescribed. The drawings are not drawn to scale and thus, do not reflect the actual measurements of the features such as the correlation of thickness to planar dimensions and the relative thickness of different layers. Further, directional terms such as up, upper, upward, down, lower, downward, left, leftward, right, and rightward are used in a relative context with an assumption that the worked surface of the later described semiconductor substrate faces up. Thus, the directional terms do not necessarily correspond to the directions based on gravitational acceleration.

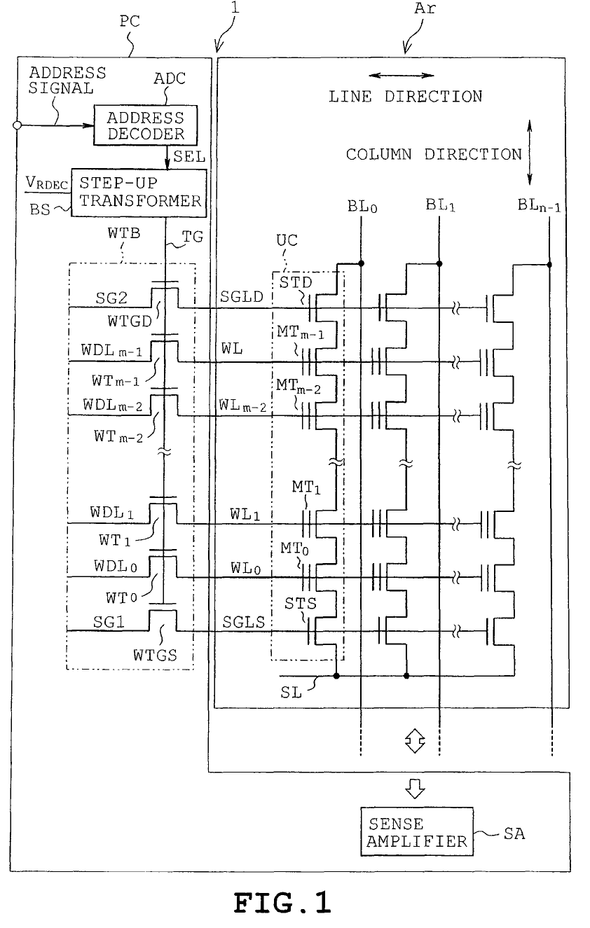

With reference to FIGS. 1 to 12D, a description will be given hereinafter on a first embodiment of a nonvolatile semiconductor storage device through a NAND flash memory application.

FIG. 1 is a schematic block diagram indicating the electrical configuration of NAND flash memory device 1. As shown in FIG. 1, NAND flash memory device 1 is provided with a memory cell region including one or more memory cell array Ar, peripheral circuit PC, and input/output interface circuit not shown. Memory cell array Ar is an array of matrix aligned memory cells and peripheral circuit PC performs reading/programming/erasing of each memory cell within memory array Ar. Memory cell array Ar is located within a first semiconductor region and peripheral circuit PC is located within a second semiconductor region.

Memory cell array Ar includes multiplicity of units of cells also referred to as cell unit UC or a NAND string. Cell unit UC includes a pair of select transistor STD and select transistor STS, and multiple memory cell transistors MT₀ to MTₘ₋₁ series connected between select transistors STD and STS as shown in FIG. 1. The count of memory cells within cell unit UC is given by m=2^{k}. A typical cell unit UC includes 32 memory cells (m=32). Each of select transistors STD is connected to a bit line which is represented as bit lines BL₀ to BLₙ₋₁ in FIG. 1, whereas each of select transistors STS is connected to a source line SL.

A row of cell units UC, which is taken along the left and right direction as viewed in FIG. 1, is referred to as a block. Each cell unit UC is associated with a bit line and thus, a block contains n number of cell units UC. Memory cell array Ar is configured by multiplicity of blocks aligned in the column direction taken along the up and down direction as viewed in FIG. 1. For simplicity, FIG. 1 only shows one block.

The memory cell region is surrounded by a peripheral circuit region and as partially shown in FIG. 1, peripheral circuit PC is located in the periphery of memory cell array Ar. Peripheral circuit PC includes address decoder ADC, sense amplifier SA, step-up circuit BS provided with a charge pump circuit, and transfer transistor WTB. Address decoder ADC is electrically connected to transfer transistor WTB through step-up circuit BS. Though not shown, peripheral circuit PC employs resistor R as one of its circuit components.

Address decoder ADC selects a given block based on an incoming address signal provided from an external component and sends block selection signal SEL to step-up circuit BS. Step-up circuit BS receives drive voltage V_{RDEC} from an external component and when receiving block selection signal SEL from address decoder ADC, steps up drive voltage V_{RDEC} and supplies the stepped up voltage to transfer transistors WTGD, WTGS, and WT₀ to WTₘ₋₁ by way of transfer gate line TG.

Transfer transistor WTB is a general identification of transfer transistor WTGD, transfer transistor WTGS, and word line transfer transistors WT₀ to WTₘ₋₁. Transfer transistor WTGD is associated with select transistor STD, whereas transfer transistor WTGS is associated with select transistor STS. Likewise, word line transfer transistors WT₀ to WTₘ₋₁ are associated with each of memory cell transistors Mt₀ to MTₘ₋₁. Transfer transistor WTB is given on a block by block basis.

Transfer transistor WTGD is configured such that either of the drain and source is connected to select gate driver line SG2, and the remaining other is connected to select gate line SGLD. Transfer transistor WTGS is configured such that either of the drain and source is connected to select gate driver line SG1, and the remaining other is connected to select gate line SGLS. Each of word line transfer transistors WT₀ to WTₘ₋₁ is configured such that either of the drain and source is uniquely connected to word line drive signal line WDL₀ to WDLₘ₋₁ respectively, and the remaining other is uniquely connected to word line WL₀ to WLₘ₋₁.

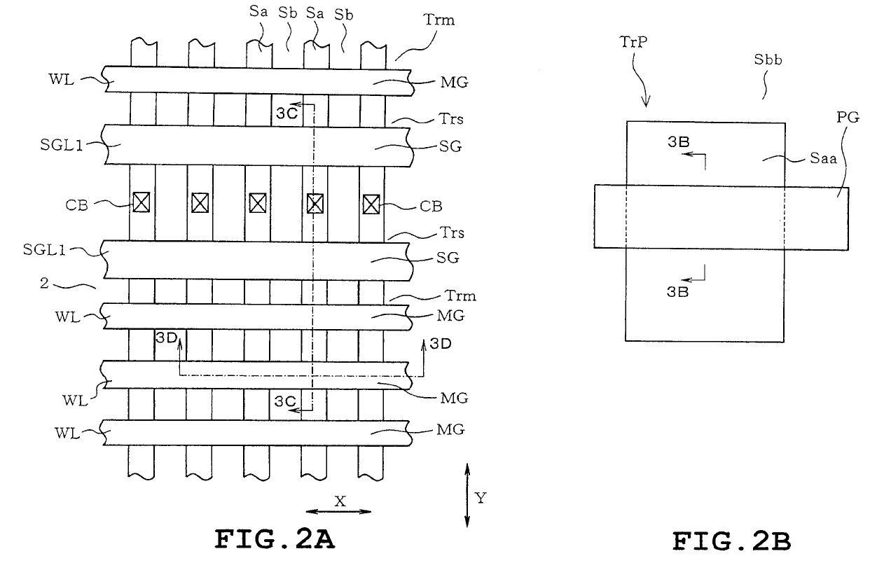

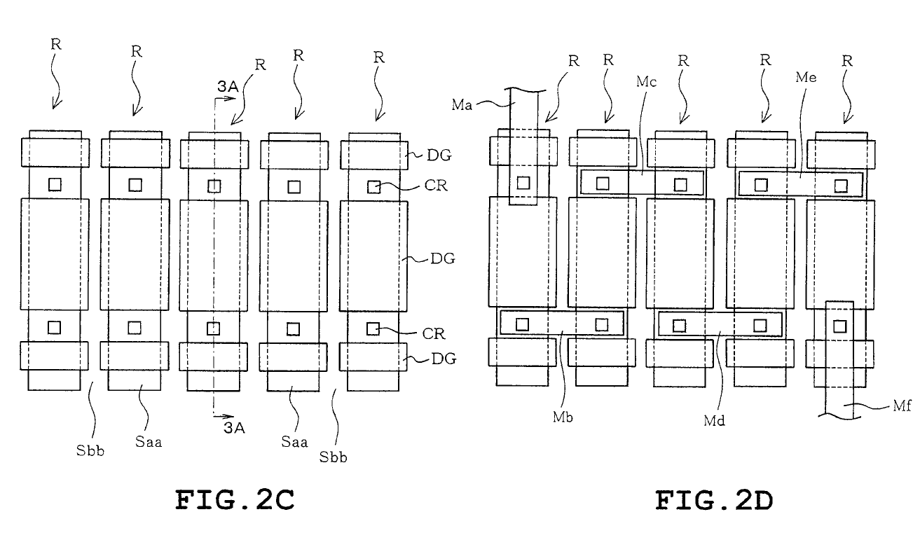

Gate electrodes SG of select transistors STD within the same block are electrically connected by common select gate line SGLD. Similarly, Gate electrodes SG of select transistors STS within the same block are electrically connected by common select gate line SGLS. As described earlier, the source of each select transistor STS is connected to common source line SL. In the descriptions directed to FIG. 2A and beyond, select transistors STD and STS are generally referred to as select transistor Trs. Further, word lines WL₀ to and bit lines BL₀ to BLₙ₋₁ are also referred to as word lines WL and bit lines BL for simplicity.

Gate electrodes MG of memory cell transistors Mt₀ to MTₘ₋₁ within the same block are each electrically connected by common word line WL₀ to WLₘ₋₁ respectively. In the descriptions directed to FIG. 2A and beyond, memory cell transistors Mt₀ to MTₘ₋₁ are generally referred to as select transistor Trm.

Gate electrodes of transfer transistors WTGD, WTGS, and WT₀ to WTₘ₋₁ within the same block are interconnected by common transfer gate line TG, which is turn, connected to an output terminal of step up circuit BS for supplying stepped up voltage. Sense amplifier SA is connected to bit lines BL₀ to BLₙ₋₁ and is further connected to a latch circuit that serves as a temporary storage of data read during a read operation. In the descriptions directed to FIG. 2A and beyond, various types of transistors formed in the peripheral circuit region are generally referred to as transistor Trp and are illustrated, in FIG. 2A and beyond, as a transistor exhibiting normal voltage tolerance level.

FIG. 2A provides a planar layout of the memory cell region in part. Memory cell region is also hereinafter referred to as a first semiconductor region. As shown in FIG. 2A, multiplicity of isolation regions Sb run in the Y direction as viewed in FIG. 2A of semiconductor substrate, exemplified as a P-type silicon substrate 2 in the first embodiment. The isolation employs an STI (shallow trench isolation) method in which trenches are filled with an insulating film. Isolation regions Sb are separated from one another in the X direction as viewed in FIG. 2A to isolate element regions Sa, running in the Y-direction, by a predetermined space interval taken along the X direction.

Still referring to FIG. 2A, multiplicity of word lines WL, spaced from one another in the Y direction by a predetermined spacing, extend in the X direction which is the direction orthogonal to the Y direction in which element region Sa extends. Above element region Sa located at the intersection with word line WL, gate electrode MG of memory cell transistor Trm is formed.

As described earlier, select gate line, illustrated as select gate line SGL1 in FIG. 2A, extend in the X direction. Above element region Sa located at the intersection with select gate line SGL1, gate electrode SG of select transistor Trs is formed.

Further, bit line contact CB is formed in element region Sa so as to be located between Y-directionally opposing select gate electrodes SG of select transistors Trs.

FIG. 2B provides a planar layout of peripheral circuit transistor Trp provided in a peripheral circuit region which is hereinafter also referred to as a second semiconductor region. Though only one is shown in FIG. 2B, the peripheral circuit region has a plurality of rectangular element regions Saa which are each surrounded by element isolation region Sbb. Peripheral circuit transistor Trp is formed within this rectangular element region Saa. Above element region Saa, isolated gate electrode PG is formed so as to extend across element region Saa. Within element region Saa, a source/drain region formed by impurity diffusion is provided on both sides of gate electrode PG.

FIG. 2C is a plan view of resistor R formed in the peripheral circuit region which exemplifies a layout of 5 resistors R. As was the case for the above described peripheral circuit transistor Trp, resistor R is formed within a rectangular element region Saa which is isolated by element isolation region Sbb. Within element region Saa, a conductive layer serving as the resistive element of resistor R is formed. Near the upper and lower edges of the conductive layer as viewed in FIG. 2C, a pair of contacts CR is provided. Apart from contact CR, the upper surface of the conductive layer has a dummy gate DG provided on it which was formed when gate structures of the memory cell transistors were formed. The conductive layer located between the pair of contact CR serves as resistor R.

FIG. 2D illustrates interconnect patterns Ma to Mf formed above the structure of FIG. 2C over an interlayer insulating film. Interconnect patterns Ma to Mf connect the 5 resistors R in series. The count of resistors R and the connection between them shown and described herein are merely examples and any number of resistors R may be connected in any way in order to obtain the desired resistivity.

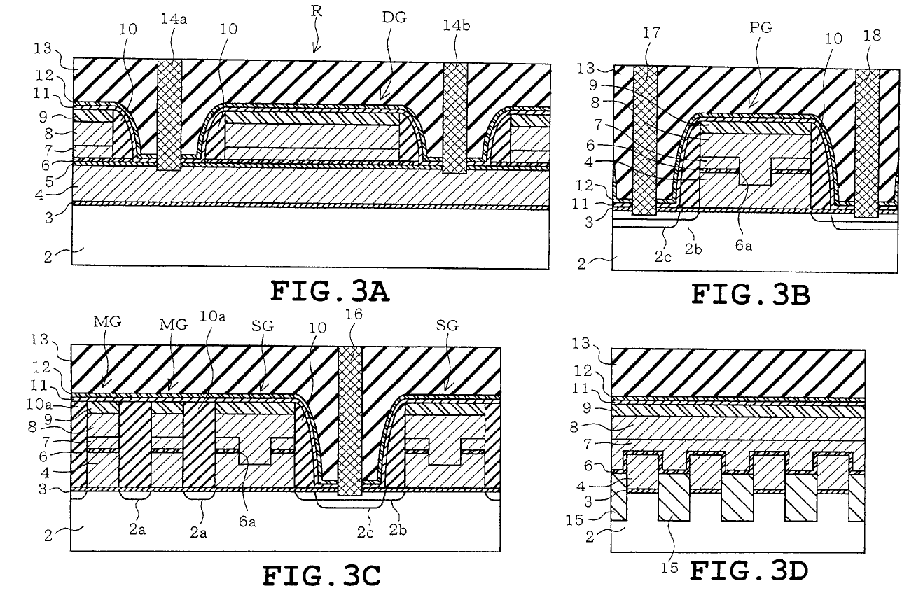

FIGS. 3A to 3D are schematic cross sectional views of the elements located in the memory cell region and the peripheral circuit region. FIG. 3A is a vertical cross sectional view of resistor R taken along line 3A-3A of FIG. 2C. FIG. 3B is a vertical cross sectional view of peripheral circuit transistor Trp taken along line 3B-3B of FIG. 2B. FIG. 3C is a vertical cross sectional view of the memory cell region taken along line 3C-3C oriented in the Y direction or bit line BL direction of FIG. 2A and illustrates the vertical cross sections of memory cell transistors Trm, select transistors Trs and bit line contact CB between the opposing select transistors Trs. FIG. 3D is a vertical cross sectional view of the memory cell region taken along line 3D-3D oriented in the X direction or word line WL direction of FIG. 2A and illustrates the vertical cross section of memory cell transistors Trm.

In FIG. 3A illustrating resistor R, silicon substrate 2 serves as element region Saa which is surrounded by element isolation region Sbb not shown which insulates and isolates the shown resistor R from other elements. Above silicon substrate 2, first gate insulating film 3 is formed which typically comprises a silicon oxide film. Above first gate insulating film 3, first conductive film serving as a resistive element of resistor R is formed which comprises polycrystalline silicon film 4.

Above polycrystalline silicon film 4, first insulating film 5 is formed which comprises a silicon nitride film. First insulating film 5 is used as a hard mask in forming the element isolation trenches. Above first insulating film 5 exclusive of the contact region, second gate insulating film 6 is formed. Above second gate insulating film 6, polycrystalline silicon films 7 and 8 are formed in the listed sequence, whereafter silicon nitride film 9 is further formed on top. Second gate insulating film 6, polycrystalline silicon films 7 and 8, and silicon nitride film 9 serve as dummy gate DG.

Along the sidewall of dummy gate DG, spacer 10 is formed which comprises a silicon oxide film. Spacer 10, the upper surface of dummy gate DG, and the exposed surface of first insulating film 5 located between dummy gates DG are covered by second insulating film 11 serving as a liner film comprising a silicon oxide film. Second insulating film 11 is further covered by third insulating film 12 serving as a liner film comprising a silicon nitride film.

Above third insulating film 12, interlayer insulating film 13 is formed so as to fill the gaps between dummy gates DG. As can be seen in FIG. 3A, contact plugs 14a and 14b are formed through interlayer insulating film 13, third insulating film 12, second insulating film 11, and first insulating film 5 on both sides of dummy gate DG so as to form contact CR that extends into the surface layer of polycrystalline silicon film 4 to establish an ohmic contact with polycrystalline silicon film 4. Resistor R employing polycrystalline silicon film 4 as a resistive element is configured as described above.

Referring now to FIGS. 3C and 3D, a description will be given on the structures of memory cell transistor Trm and select transistor Trs. As can be seen FIGS. 3C and 3D, first gate insulating film 3 is formed above silicon substrate 2. Gate electrode MG of memory cell transistor Trm and gate electrode SG of select transistor Trs are formed above first gate insulating film 3. In the first embodiment, memory cell transistor Trm comprises gate electrode MG and source/drain region 2a formed in silicon substrate 2 located on both sides of gate electrode MG. As described earlier, multiple memory cell transistors Trm are series connected in the Y direction to form cell unit UC which terminate with a pair of select transistors Trs provided on both Y directional ends.

Gate electrode MG of memory cell transistor Trm includes polycrystalline silicon film 4 serving as floating gate electrode FG, second gate insulating film 6, polycrystalline silicon films 7 and 8 serving as control gate electrode CG, and silicon nitride film 9 stacked in the listed sequence above first gate insulating film 3. Second gate insulating film 6 may take an ONO structure comprising a stack of oxide/nitride/oxide films, which may be provided with additional bottom and top nitrides to take a NONON structure or may also comprise a high dielectric constant insulating film.

In the surface layer of silicon substrate 2 located between gate electrodes MG and between gate electrodes SG and MG, source/drain region 2a is formed. In the surface layer of silicon substrate 2 located between gate electrodes SG, LDD (lightly doped drain) region 2b is formed which serves as a drain region. Source/drain region 2a and LDD region 2b are formed by doping impurities into the surface layer of silicon substrate 2. Further in the surface layer of silicon substrate 2 located between gate electrodes SG, drain region 2c heavily doped with impurities is formed to obtain an LDD structure.

Select gate electrode SG of select transistor Trs is substantially identical in structure to gate electrode MG of memory cell transistor Trm and thus, is configured by polycrystalline silicon film 4, second gate insulating film 6, polycrystalline silicon films 7 and 8, and silicon nitride film 9 stacked in the listed sequence above first gate insulating film 3. Select gate electrode SG differs from memory cell gate electrode MG in that through hole 6a penetrates the central portion of second gate insulating film 6 to electrically conduct polycrystalline silicon films 4, 7 and 8.

Along the opposing sidewalls of gate electrodes SG shown in FIG. 3C, spacer 10 is formed which comprises a silicon oxide film. Between the adjacent gate electrodes MG as well as between gate electrodes MG and SG, a gap filling intergate insulating film 10a is formed up to the level of silicon nitride film 9. Intergate insulating film 10a and spacer 10 are both made of a silicon oxide film.

The upper surfaces of gate electrodes MG and SG, the upper surface of intergate insulating film 10a, spacer 10, and the upper surface of first gate insulating film 3 located between gate electrodes SG are covered by second insulating film 11 serving as a liner film comprising a silicon oxide film. Second insulating film 11 is further covered by third insulating film 12 serving as a liner film comprising a silicon nitride film.

Above third insulating film 12, interlayer insulating film 13 is formed so as to fill the gaps between gate electrodes SG and to cover the upper surfaces of gate electrode MG and SG. As can be seen in FIG. 3C, contact plug 16 is formed through interlayer insulating film 13, third insulating film 12, second insulating film 11, and first gate insulating film 3 located between gate electrodes SG so as to contact silicon substrate 2.

Referring now to FIG. 3B, a description will be given on the structure of peripheral circuit transistor Trp. Transistor Trp is substantially identical in structure to select transistor Trs. For peripheral circuit transistor Trp as well, silicon substrate 2 serves as element region Saa which is surrounded by element isolation region Sbb not shown. As was the case of transistors Trm and Trs, transistor Trp is formed above first gate insulating film 3 which is provided above silicon substrate 2. The level of voltage tolerance varies depending upon the type of transistor Trp and thus, the thickness of first gate insulating film 3 varies accordingly. For instance, a thick first gate insulating film 3 may be formed for transistor Trp requiring high level of voltage tolerance.

Gate electrode PG of transistor Trp is configured by polycrystalline silicon film 4, second gate insulating film 6, polycrystalline silicon films 7 and 8, and silicon nitride film 9 stacked in the listed sequence above first gate insulating film 3. In gate electrode PG, through hole 6a penetrates the central portion of second gate insulating film 6 to electrically conduct polycrystalline silicon films 4, 7 and 8.

Along the sidewall of gate electrodes PG shown in FIG. 3B, spacer 10 is formed. Gate electrode PG differs from gate electrode SG in that spacer 10 is formed on both of its sides as apparent from the comparison of FIGS. 3C and 3B.

The upper surface of gate electrode PG, spacer 10, and the upper surface of first gate insulating film 3 located above silicon substrate 2 located on both sides of gate electrodes SG are covered by second insulating film 11 serving as a liner film. Second insulating film 11 is further covered by third insulating film 12 serving as a liner film comprising a silicon nitride film.

Above third insulating film 12, interlayer insulating film 13 is formed. As can be seen in FIG. 3C, contact plugs 17 and 18 are formed through interlayer insulating film 13, third insulating film 12, second insulating film 11, and first gate insulating film 3 on both sides of gate electrode PG so as to extend into the surface layer of polycrystalline silicon film 4.

According to the above described configuration, NAND flash memory device 1 including resistor R can be provided without significantly altering the structure of a general NAND flash memory device. Further, because contact plugs 14a and 14b are placed in direct physical contact with polycrystalline silicon film 4 which serves as the resistive element of resistor R, resistor R is subjected to relatively less factors of variation in resistivity as compared to conventional structures, thereby achieving relatively less resistivity shifts which in turn improves the design margin.

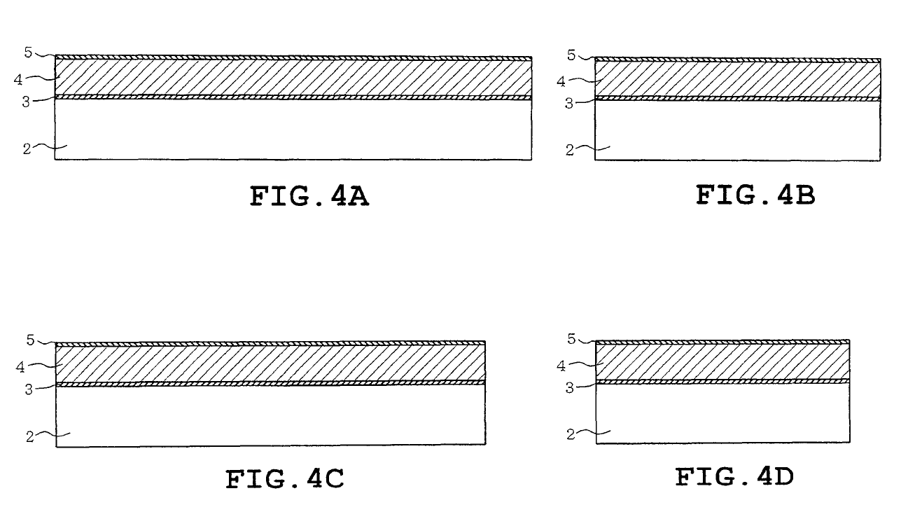

Next, one example of a manufacturing process flow of the above described configuration will be described with reference to FIGS. 4A to 12D. The following descriptions will focus on the features of the first embodiment and thus, known steps may be added or removed from the process flow as required. Further, the sequence of the process flow may be rearranged if practicable.

Referring now to FIGS. 4A to 4D, gate insulating film 3 comprising a silicon oxide film of a predetermined thickness is formed above silicon substrate 2 typically by thermal oxidation. Then, polycrystalline silicon film 4 also referred to as a first conductive film is formed above first gate insulating film 3. Polycrystalline silicon film 4 may be doped with impurities such as phosphorous (P) in the dopant concentration ranging from 1×10²⁰ to 5×10²⁰ atoms/cm² which exhibits a sheet resistance ranging between 150 to 300 Ω/cm².

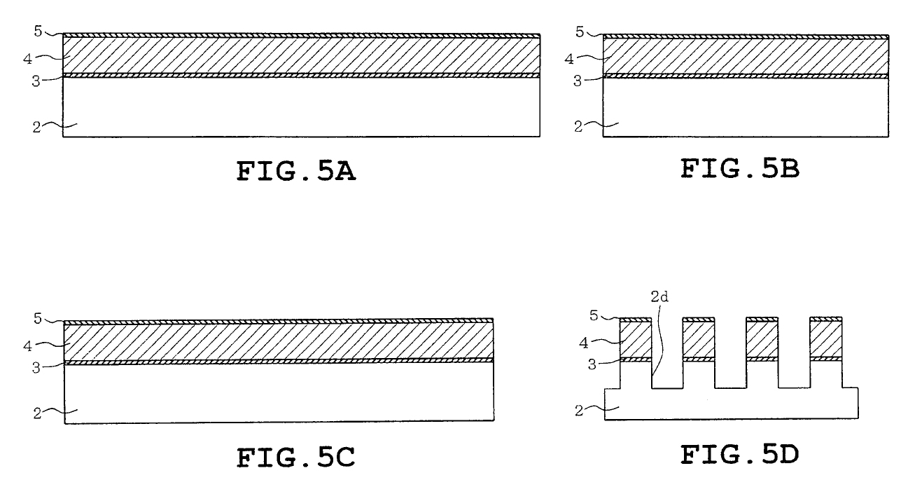

Referring now to FIGS. 5A to 5D, the above described feature is patterned by photolithograpy typically using a photoresist. First insulating film 5 comprising a silicon nitride film is anisotropically etched typically by RIE (Reactive Ion Etching) to form a hard mask. Then, using the hard mask, polycrystalline silicon film 4, first gate insulating film 3, and silicon substrate 2 are etched anisotropically to form element isolation trenches 2d having a predetermined thickness as shown in FIG. 5D. This forms element region Sa serving as an element region isolated by element isolation trenches 2d in the surface layer of silicon substrate 2. At the same time, element isolation trenches are formed in the peripheral circuit region to obtain element region Saa.

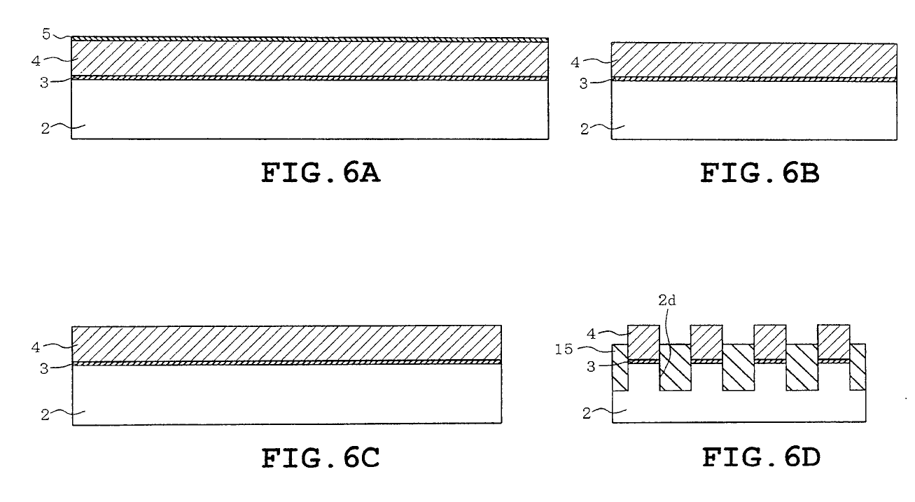

Referring now to FIGS. 6A to 6D and more specifically to FIG. 6D, element isolation trenches 2d are overfilled with element isolation insulating film 15 typically comprising a silicon oxide film. The silicon oxide film may be formed by spin coating a polysilazane solution using SOG (Spin On Glass) method and vaporizing the solvent through thermal treatment.

Then, the excess element isolation insulating film 15 is typically etched back or polished away by CMP (Chemical Mechanical Processing) to leave element isolation insulating film 15 within element isolation trenches 2d. Thereafter, the upper surface of element isolation insulating film 15 within element isolation trenches 2d is further etched back to be lowered to approximately mid height of polycrystalline silicon film 4.

Then, a photoresist pattern covering the region for forming resistor R is formed by photolithography. Using the photoresist pattern as a mask, first insulating film 5 is etched away from the memory cell region and from portions of the peripheral circuit region where transistors Trp are formed as shown in FIGS. 6B to 6D while remaining above the region where resistor R is formed as shown in FIG. 6A.

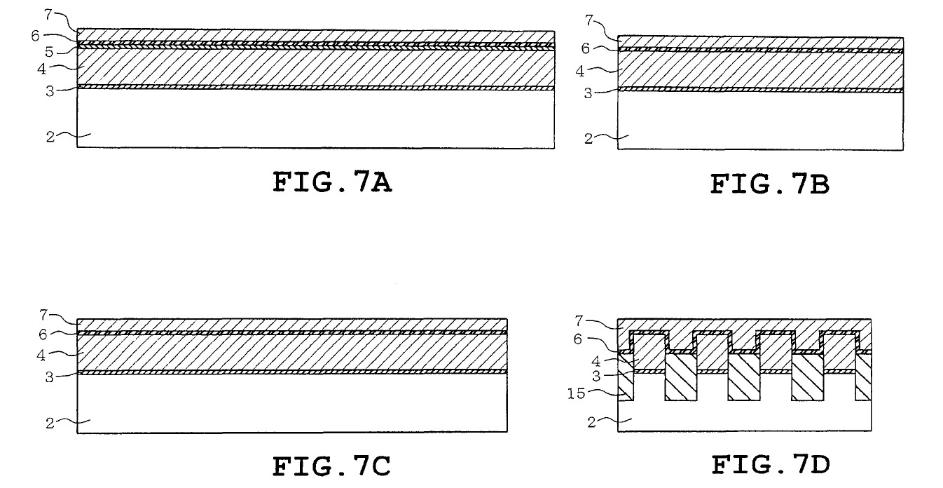

Referring now to FIGS. 7A to 7D, second gate insulating film 6 is blanketed above the obtained structure. As shown in FIG. 7D, second gate insulating film 6 conforms with the topography of the underlying structure defined by the protruding pillars of polycrystalline silicon film 4 and the intervening gaps created by the lowered element isolation insulating films 15. Second gate insulating film 6 typically comprises an ONO film or a NONON film. Then, above second gate insulating film 6, polycrystalline silicon film 7 serving as second conductive film is further formed to over fill the gaps and planarize the stepped topography.

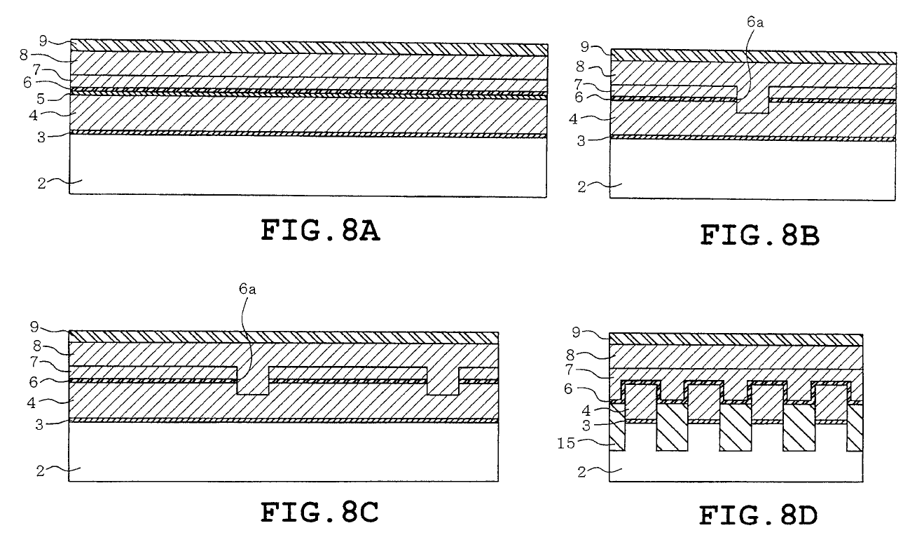

Referring now to FIGS. 8A to 8D, opening 6a is defined through a predetermined location of polycrystalline silicon film 7, second gate insulating film 6, and polycrystalline silicon film 4 by photolithography. This is to establish an electrical conduction between polycrystalline silicon film 4 and polycrystalline silicon film 7 in gate electrode SG of select transistor Trs and gate electrode PG of peripheral circuit transistor Trp as shown in FIGS. 8B and 8C. Opening 6a extends into polycrystalline silicon film 4 such that polycrystalline silicon film 4 is slightly recessed. Then, opening 6a is overfilled with polycrystalline silicon film 8 so as to be blanketed over polycrystalline silicon film 7. Thereafter, silicon nitride film 9 is further formed above polycrystalline silicon film 8.

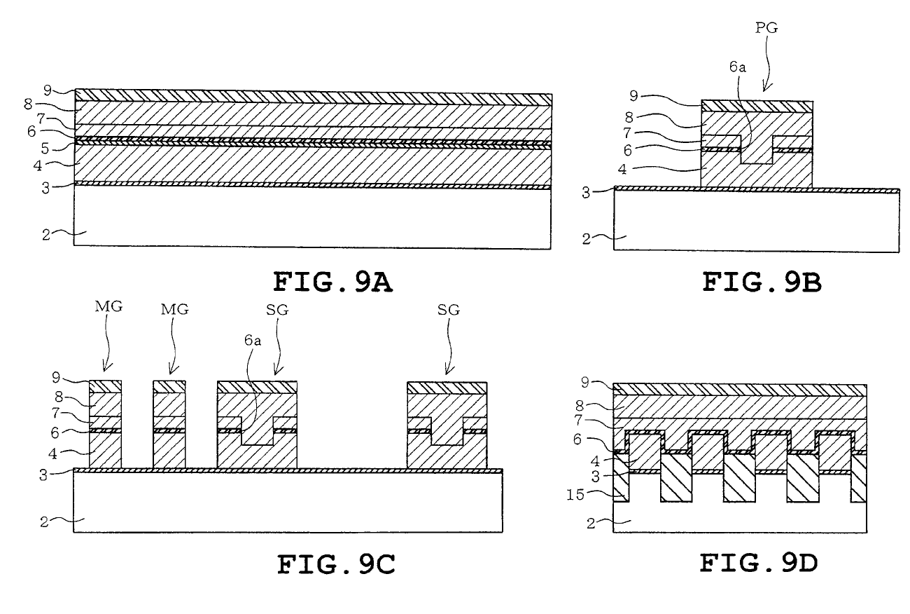

Referring now to FIGS. 9A to 9D, gate structures are formed using the topmost silicon nitride film 9 as a hard mask. Using photolithography, a photoresist pattern is formed that covers the regions for forming resistor R, while a line and space photoresist pattern is formed in the memory cell region for forming gate electrodes MG and SG and a required pattern is formed in the peripheral circuit region for forming gate electrode PG. Using the photoresist pattern, silicon nitride film 9 is etched to obtain a hard mask which is in turn used for etching polycrystalline silicon film 8, 7, second gate insulating film 6, and polycrystalline silicon film 4 in the listed sequence to form gate electrodes MG, SG and PG and partially expose first gate insulating film 3 as shown in FIGS. 9B to 9D.

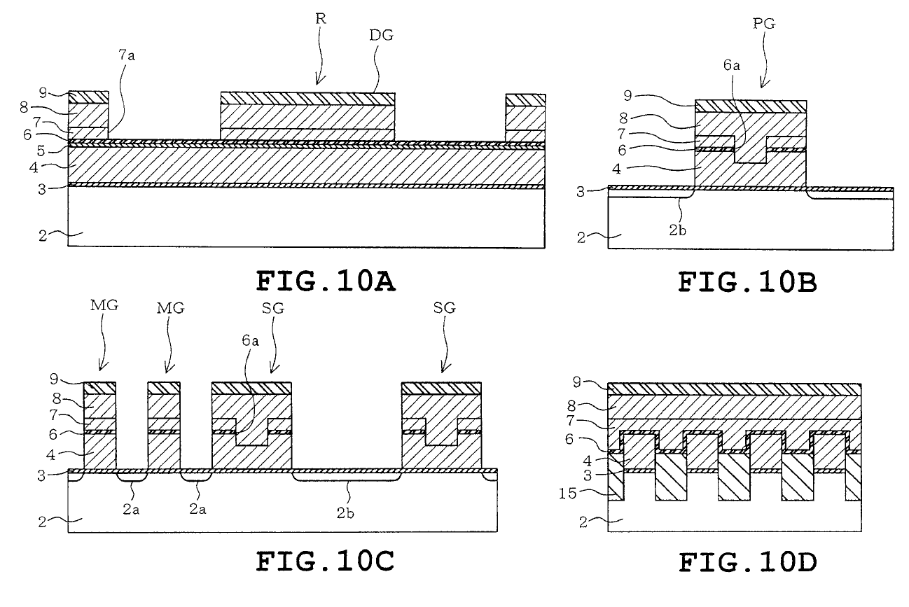

Referring now to FIGS. 10A to 10D, using silicon nitride film 9 as a mask, N-type impurities such as phosphorous are introduced by ion implantation on both sides of gate electrodes MG, SG, and PG which is followed by a thermal treatment to form source/drain region 2a and LDD 2b as shown in FIGS. 10B and 10C.

Then, using photolithography, a photoresist pattern is formed in the regions where resistor R is to be formed and the photoresist pattern is further patterned to form an opening in the regions where a contact is to be formed. At this instance, other regions such as the memory cell region and portions of the peripheral circuit region where transistor Trp is to be formed are covered by photoresist. Then, silicon nitride film 9 is etched by RIE to forma hard mask which is in turn used to anisotropically etch polycrystalline silicon films 8 and 7 to form opening 7a through polycrystalline silicon films 8 and 7. Polycrystalline silicon films 8 and 7 are thus, isolated to form dummy gate DG. Unlike the formation of gate electrodes SG, MG, and PG described with references to FIG. 9B to 9D, polycrystalline silicon film 4 remains unetched in the formation of dummy gate DG as can be seen in FIG. 10A and thus, first gate insulating film 3 remains unexposed.

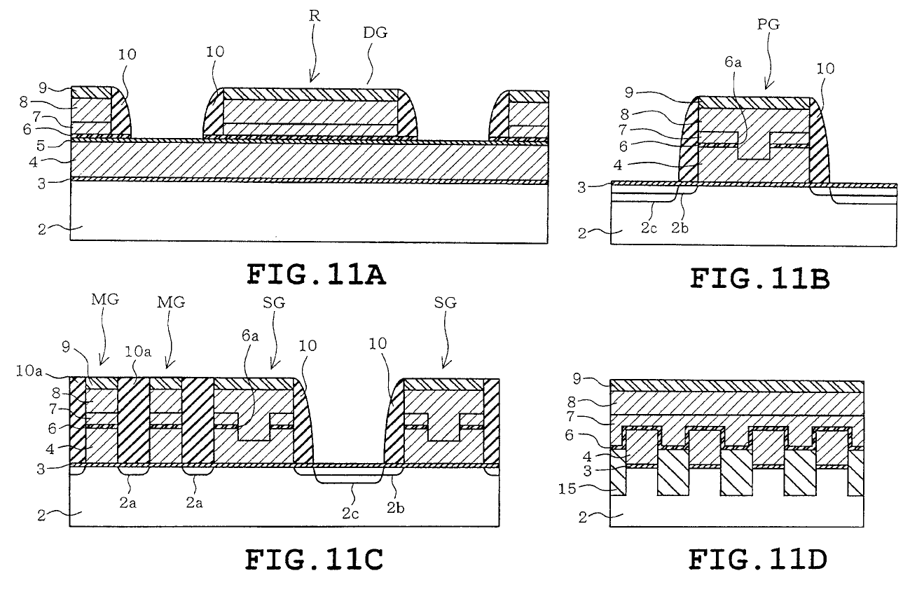

Referring now to FIGS. 11A to 11D, a silicon oxide film is blanketed over the above described structure in a predetermined thickness so as to cover gate electrodes MG, SG, and PG as well as dummy gate DG and fill the gaps between gate electrodes MG and between gate electrodes MG and SG. The blanket silicon oxide film is thereafter etched back so that intergate insulating film 10a is formed between gate electrodes MG and between gate electrodes MG and SG and spacer 10 is formed on the opposing sidewalls of opposing gate electrodes SG as well as on the sidewall of gate electrode PG. When the silicon oxide film is etched back to form spacer 10 for dummy gate DG, second gate insulating film 6 is etched as shown in FIG. 11A, in which case first gate insulating film 5 may be used as an etch stop.

Then, using spacer 10 as a mask, the surface layer of silicon substrate 2 located between opposing gate electrodes SG and located on both sides of gate electrode PG are heavily doped with impurities, such as phosphorous or arsenic in case of N-type impurities, by ion implantation. This is followed by a thermal treatment for activating the impurities and forming drain/source region 2c taking an LDD structure as shown in FIGS. 11B and 11C to be used in contact formation.

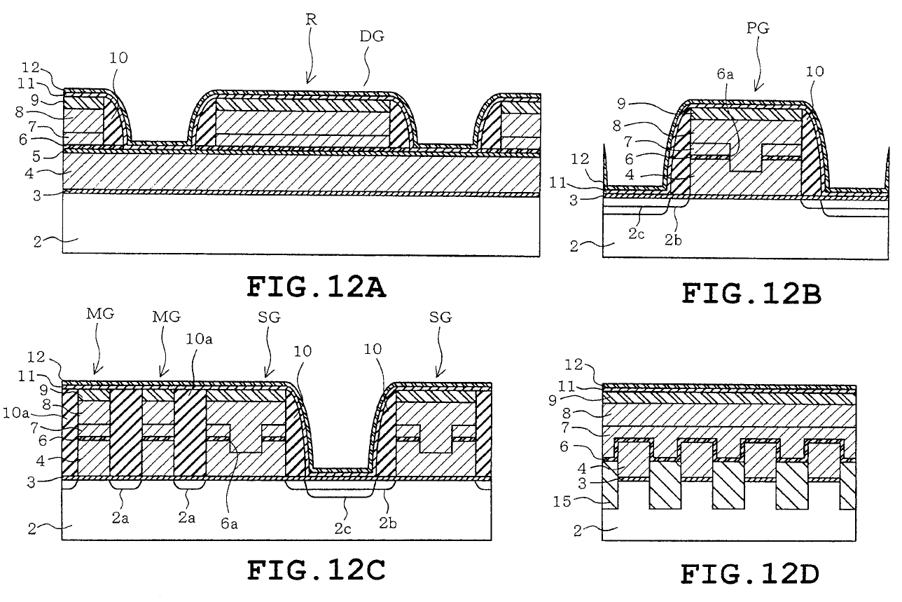

Referring now to FIGS. 12A to 12D, a second insulating film 11 comprising a silicon oxide film and serving as a liner film is blanketed over the above described structure in a predetermined thickness. That is, as shown in FIG. 12A, second insulating film 11 is lined above silicon nitride film 9 located above the upper surface of dummy gate DG, along spacer 10, and above the exposed surface of first insulating film 5. Then, third insulating film 12 comprising a silicon nitride film and serving as a liner film is further formed in a predetermined thickness above second insulating film 11.

Similarly, as shown in FIG. 12C, the above described second insulating film 11 is formed in a predetermined thickness above silicon nitride film 9 located above the upper surface of gate electrodes MG and SG, along spacer 10 formed along the opposing sidewalls of opposing gate electrodes SG, and above the exposed surface of first gate insulating film 3. Then, third insulating film 12 comprising a silicon nitride film and serving as a liner film is further formed in a predetermined thickness above second insulating film 11.

As a result, gaps lined with a laminate of second insulating film 11 and third insulating film 12 is formed on both sides of dummy gate DG of resistor R. Similarly, a gap lined with a laminate of second insulating film 11 and third insulating film 12 is formed in the region between the opposing gate electrodes SG.

Then, referring to FIGS. 3A to 3D, a planar interlayer insulating film 13 comprising a silicon oxide film with good flow capabilities is formed entirely across the above described structure so as to overfill the gap between opposing gate electrodes SG and the gap on both sides of dummy gate DG of resistor R. Alternatively, the formation of interlayer insulating film 13 may be performed in 2 steps. In the first step, the gaps are overfilled by deposition of a first layer of interlayer insulating film and thereafter planarized by CMP or etch back. Then in the second step, a second layer of interlayer insulating film is further deposited to obtain a thick interlayer insulating film 13 comprising a combination of the first layer and the second layer.

Then, contact plugs are formed by photolithography. Contact plugs 14a and 14b for resistor R, contact plugs 16 for bit line contacts typically formed in the memory cell region, and contact plugs 17 and 18 for transistor TrP in the peripheral circuit region may be etched in the same etching process.

The formation of a contact plug typically begins with an application of a photoresist and patterning the same for contact hole formation. Then, using the patterned photoresist as a mask, interlayer insulating film 13 comprising a silicon oxide film is etched anisotropically by RIE. Third insulating film 12 underlying interlayer insulating film 13 comprises a silicon nitride film and thus, by configuring the RIE to progress with selectivity to silicon nitride film, the RIE may be stopped when encountering the upper surface of third insulating film 12 in the regions for forming resistor R, the memory cell region, and the regions for forming transistor Trp in the peripheral circuit region.

In the regions for forming resistor R, third insulating film 12 is formed above polycrystalline silicon film 4, and thus, the depth of interlayer insulating film 13 etching is relatively shallower as compared to the memory cell region and the peripheral circuit region where transistor Trp is formed. Thus, by configuring the RIE to progress with selectivity to silicon nitride film as described above, both shallow and deep etching can be performed simultaneously. Further, in the regions for forming resistor R, first insulating film 5 comprising a silicon nitride film also serves as an etch stop. Thus, even when the thickness of third insulating film 12 varies depending upon location, the excessive etching carried out in relatively thin portions of the third insulating film 12 can be reliably absorbed by the underlying first insulating film 5.

Thereafter, the contact holes are overfilled with metal contact plug material and the excess metal above interlayer insulating film 13 is polished away by CMP to form contact plugs 14a, 14b, and 16 to 18. The contact plug material may comprise tungsten or polycrystalline silicon. Though not shown, additional levels of interconnect are formed further above to complete NAND flash memory device 1.

In the first embodiment, NAND flash memory device 1 including resistor R in which contact plugs 14a and 14b are placed in direct physical contact with polycrystalline silicon film 4 can be provided without significantly altering the manufacturing process flow employed for a general NAND flash memory device.

Further, first insulating film 5 used as the hard mask for forming element isolation trench 2d is left on the upper surface of polycrystalline silicon film 4 located in the region for forming resistor R. Thus, first insulating film 5 and third silicon insulating film 12 lined above first insulating film 5 may serve as a double etch stop layer comprising silicon nitride film against the etching progressing through interlayer insulating film 13 comprising silicon oxide film when forming the contact holes for contact plugs 14a and 14b. This improves the process margin and improves the quality of contact plug formation.

Still further, when polycrystalline silicon films 7 and 8 are etched to form the dummy gate DG for the subsequent formation of contact plugs 14a and 14b of resistor R, second gate insulating film 6 may be used as an etch stop. Further, the dummy gates DG are left to remain in the feature. This prevents formation of a wide sparse region and provides regularity in the patterns.

Yet further, NAND flash memory device 1 employs polycrystalline silicon film 4 as a resistive element of resistor R and thereby exhibits stable resistivity. Further, the direct physical contact between polycrystalline silicon film 4 and contact plugs 19a and 14b eliminates the intervention of polycrystalline silicon films 7 and 8 serving as the control gate electrode as well as the second gate insulating film 6, thereby suppressing disturbs typically originating from interfacial resistance.

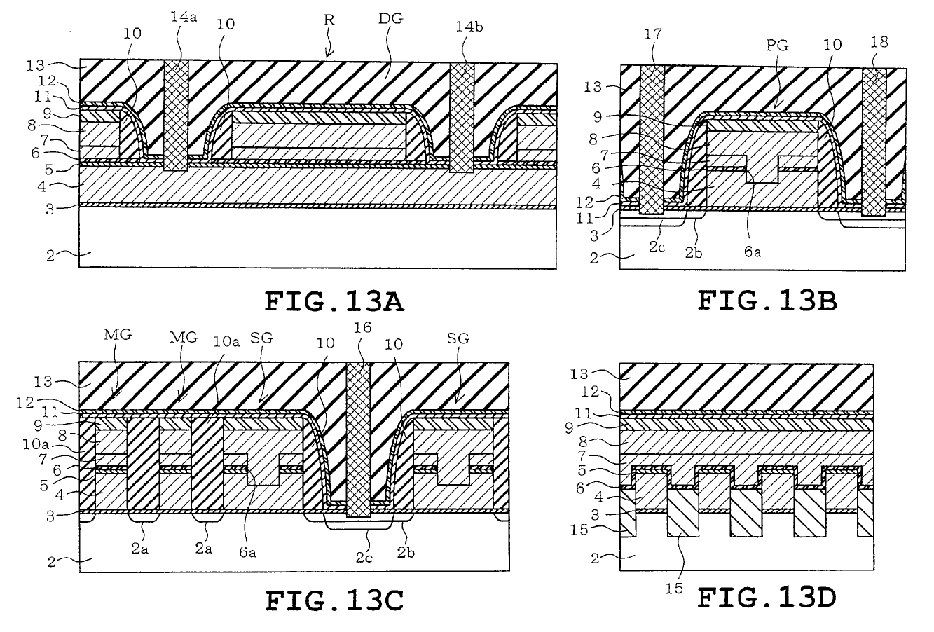

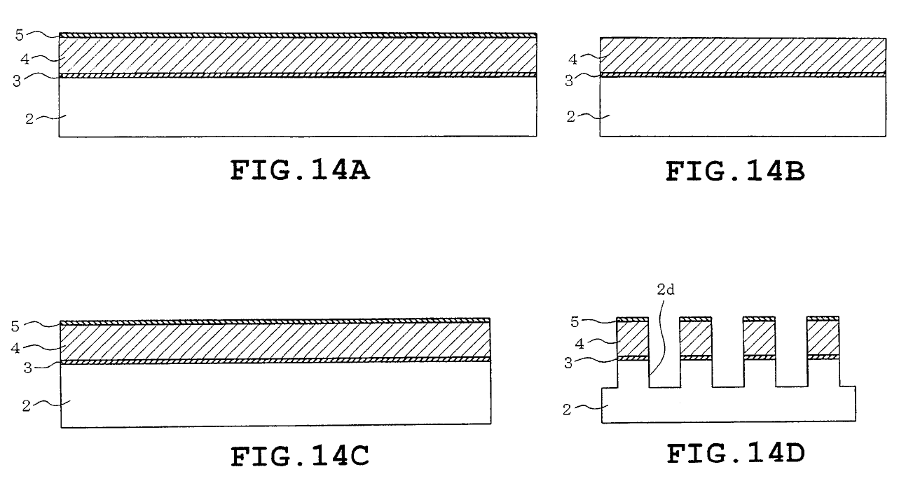

FIGS. 13A to 14D illustrate a second embodiment. Description will be given hereinafter on the differences from the first embodiment.

In the first embodiment, first insulating film 5 remained between polycrystalline silicon film 4 and second gate insulating film 6 only in resistor R and not in transistors Trs, Trm, and Trp. The second embodiment not only allows first insulating film 5 to remain in resistor R as shown in FIG. 13A, but also in memory transistor Trm. FIGS. 13C and 13D shows first insulating film 5 remaining between polycrystalline silicon film 4 and second gate insulating film 6.

The above described configuration is advantageous in that provision of first insulating film 5 comprising silicon nitride film suppresses high electric field leakage current in gate electrode MG of memory cell transistor Trm. More specifically, second gate insulating film 6 located between the floating gate electrode and the control gate electrode is subjected to high electric field which leads to high electric field leakage current. The additional first insulating film 5, that is, the silicon nitride film provided below second gate insulating film 6 relaxes the electric field and consequently suppresses the high electric field leakage current.

The manufacturing process flow for obtaining the above described structure will be described hereinafter with reference to FIGS. 14A to 14D. In the first embodiment, first insulating film 5 was removed in the process described with reference to FIGS. 5A to 5D with the exception of the region for forming resistor R. In the second embodiment, first insulating film 5 located in the memory cell region is also configured to remain above polycrystalline silicon film 4. Accordingly, the photoresist used in removing first insulating film 5 is patterned such that opening is defined only above the portions of the peripheral circuit region where transistor Trp is to be formed. Etching performed based on such photoresist pattern will remove first insulating film 5 from the portion of the peripheral circuit region where transistor Trp is formed as shown in FIG. 14B and maintain first insulating film 5 in the memory cell region and the region for forming resistor R as shown in FIGS. 14A, 14C, and 14D.

The rest of the manufacturing process flow remains the same from those of the first embodiment which provides the structures illustrated in FIGS. 13A to 13D.

The above described embodiments may be modified or expanded as follows.

In the first and the second embodiment, first insulating film 5 was made of silicon oxide film, whereas second insulating film 11 and third insulating film 12 were made of silicon nitride film. The ingredients for these insulating films are interchangeable and may further incorporate other choice of ingredients.

The above described embodiments were implemented through resistor provided in the peripheral circuit region. Alternative embodiments may be implemented through other circuit elements that utilize the first conductive film. One example of such circuit element may be capacitor comprising a first electrode configured by the first conductive film and a second electrode configured by a semiconductor substrate and a first gate insulating film interposing the first and the second electrode.

The above described embodiments were directed to NAND flash memory device 1, however, other embodiments may be directed to other nonvolatile semiconductor storage devices such as NOR flash memory and EERROM. The above described embodiments may be implemented through a memory device having single bit memory cell or multi-bit memory cell.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device, comprising:
a semiconductor substrate;
a first semiconductor region being formed in the semiconductor substrate and being delineated by a first element isolation trench filled with an isolation insulating film;
a second semiconductor region being formed in the semiconductor substrate and being delineated by a second element isolation trench filled with the isolation insulating film;
a memory cell transistor formed in the first semiconductor region, the memory cell transistor including a first gate insulating film, a memory gate electrode including a stack of, a first conductive film, a second gate insulating film, and a second conductive film formed above the first gate insulating film;
a resistor formed in the second semiconductor region, the resistor including a stack of the first gate insulating film and the first conductive film; and
a first and second contact plug contacting the first conductive film of the resistor.

2. The device according to claim 1, wherein the first conductive film comprises a polycrystalline silicon film.

3. The device according to claim 1, wherein the first conductive film in the second semiconductor region contains impurities for controlling resistivity.

4. The device according to claim 1, wherein two or more resistors are provided in the second semiconductor region.

5. The device according to claim 4, wherein a predetermined number of the resistors are series connected to constitute a resistor producing a predetermined resistivity.

6. The device according to claim 1, wherein the resistor further includes a first insulating film above the first conductive film, and wherein the first and the second contact plug extends through the first insulating film to contact the first conductive film.

7. The device according to claim 6, wherein the first insulating film comprises a silicon nitride film.

8. The device according to claim 7, wherein the first insulating film is further provided above the first conductive film and below the second gate insulating film of the memory gate electrode.

9. The device according to claim 1, wherein the resistor further includes, between the first and the second contact plug, a stack including the second gate insulating film and the second conductive film.

10. A nonvolatile semiconductor storage device, comprising:
a semiconductor substrate;
a first semiconductor region being formed in the semiconductor substrate and being delineated into strips by a plurality of equally spaced first element isolation trenches filled with an isolation insulating film;
a second semiconductor region being formed in the semiconductor substrate and being delineated into a rectangle by a second element isolation trench filled with the isolation insulating film;
a memory cell transistor formed in the first semiconductor region, the memory cell transistor including a first gate insulating film, a memory gate electrode including a stack of a first conductive film, a first insulating film, a second gate insulating film, and a second conductive film formed above the first gate insulating film;
a select transistor formed in the first semiconductor region and located adjacent to the memory cell transistor, the select transistor including the first gate insulating film, a select gate electrode including a stack of the first conductive film, the first insulating film, the second gate insulating film, and the second conductive film formed above the first gate insulating film;
a resistor formed in the second semiconductor region, the resistor including a stack of the first gate insulating film, the first conductive film and the first insulating film;
a second insulating film lined along the memory gate electrode, the select gate electrode, and the resistor as well as along the first gate insulating film located between the select gate electrodes;
a third insulating film formed above the second insulating film;
a fourth insulating film formed above the third insulating film so as to fill the gap between the select gate electrodes and to cover an upper surface of the resistor;
a first contact plug extending through the fourth insulating film, the third insulating film, and the second insulating film located between the select gate electrodes to contact the first semiconductor region;
a second contact plug and a third contact plug extending through the fourth insulating film, the third insulating film, the second insulating film, and the first insulating film located between the select gate electrodes to contact the second semiconductor region;
the resistor including, above the first insulating film, a stack of the second gate insulating film and the second conductive film located between the second and the third contact plugs.

11. The device according to claim 10, wherein the first insulating film comprises a silicon nitride film, the second insulating film comprises a silicon oxide film, and the third insulating film comprises a silicon nitride film.

12. The device according to claim 10, wherein the second semiconductor region further includes a peripheral circuit transistor including the first gate insulating film, a peripheral circuit transistor gate electrode including a stack of the first conductive film and the second conductive film formed above the first gate insulating film.

13. The device according to claim 10, wherein the memory cell transistor further includes a source and drain region and the memory gate electrode of the memory cell transistor is series connected to another memory gate electrode of another memory cell transistor so as to share the source and drain regions; and wherein the resistor is configured to be used for a peripheral circuit formed in the second semiconductor region.

14. The device according to claim 10, wherein the device comprises a NAND flash memory device.

15. A method of forming a nonvolatile semiconductor storage device, comprising:
forming a first gate insulating film above a semiconductor substrate, a first conductive film above the first gate insulating film, and a first insulating film above the first gate insulating film;
forming an element isolation trench into the semiconductor substrate by etching the first conductive film, the first gate insulating film, and the semiconductor substrate using the first insulating film as a mask;
filling the element isolation trench with an element isolation insulating film;
removing the first insulating film located in a memory cell transistor forming region while leaving the first insulating film located in a resistor forming region;
forming a second gate insulating film in the resistor forming region and the memory cell transistor forming region;
forming a second conductive film above the second gate insulating film;
partially etching the second conductive film, the second gate insulating film, and the first conductive film in the memory cell transistor forming region to form a memory gate electrode;
partially etching the second conductive film in the resistor forming region;
etching the second gate insulating film in the resistor forming region to form a contact region;
forming a second insulating film so as to cover the memory gate electrode and the remaining second conductive film in the resistor forming region;
forming a third insulating film above the second insulating film; and
forming a first contact plug and a second contact plug extending through the third insulating film, the second insulating film, and the first insulating film in the resistor forming region.

16. The method according to claim 15, wherein the first contact plug is formed on a first side of the remaining second conductive film and the second contact plug is formed on a second side of the remaining second conductive film opposite the first side.

17. The method according to claim 15, wherein the first insulating film comprises a silicon nitride film, the second insulating film comprises a silicon oxide film, and the third insulating film comprises a silicon nitride film.

18. The method according to claim 17, wherein forming the contact plug includes etching the third insulating film and the second insulating film using the first insulating film as an etch stop and thereafter etching away the first insulating film to form a contact hole.

19. The method according to claim 15, wherein partially etching the second conductive film in the resistor forming region forms a dummy gate electrode comprising the partially etched second conductive film, which is followed by blanketing a silicon oxide film and etching back the silicon oxide film to forma spacer along a first side of the dummy gate electrode and a second side of the dummy gate electrode opposite the first side.

20. The method according to claim 15, wherein forming the first conductive film includes forming a polycrystalline silicon film and doping impurities into the polycrystalline silicon film at a predetermined dopant concentration.
